(19) United States
(12) Patent Application Publication
(10) Pub. No.: US 2026/0346636 A1
(43) Pub. Date: Nov. 5, 2026

(54) METHOD FOR USING A HARD STAMP TO PRODUCE A SOFT STAMP

(71) Applicant: EV GROUP E. THALLNER GMBH, St. Florian am Inn (AT)

(72) Inventors: Walter ZORBACH, St. Florian am Inn (AT); Jonas KHAN, St. Florian am Inn (AT)

(73) Assignee: EV GROUP E. THALLNER GMBH, St. Florian am Inn (AT)

(21) Appl. No.: 19/485,750

(22) PCT Filed: Jun. 29, 2023
(86) PCT No.: PCT/EP2023/067845

§ 371 Date: Nov. 19, 2025

(51) Int. Cl. B44B 5/00; G03F 7/00

(52) U.S. Cl. CPC B44B 5/009; G03F 7/0002; G03F 7/0015

(57) ABSTRACT

The invention relates to a method and a device for embossing a soft stamp and a device for embossing and a soft stamp. Structures are produced on the soft stamp during the embossing with the hard stamp and a coating is provided for reducing the adhesive properties on the soft stamp.

The present invention relates to a method for the production, in particular for the embossing, of a soft stamp or a soft stamp embossing compound with a master stamp. These master stamps or hard stamps comprise structures to be impressed, which are transferred during embossing onto the soft stamp.

In the prior art, micro- and/or nanostructures are regularly produced either photolithographically and/or with the aid of imprint lithography. Imprint lithography is understood to mean a method in which micro- and/or nanometre size structures are embossed in a material by means of a stamp. The material is in particular an embossing material applied on a substrate. Such imprint methods have increasingly gained in importance in recent years, since they can be carried out more quickly, more effectively and more cost-favourably than many photolithographic methods. Furthermore, it has been shown that the achievable resolution by means of imprint-lithographic methods is by no means inferior to the resolution that can be achieved with the aid of photolithography. In some cases, such as in the so-called “first print”, better resolution can be achieved by imprint lithography than with conventional lithography.

Most embodiments of the known devices for imprint lithography are incorporated into so-called mask aligners or are designed as an independent system, but which cannot usually process substrates larger than 300 mm.

Aligners are particularly well suited for special imprint systems, since they have already found widespread use for photolithography in the semiconductor industry. It is thus expedient for suppliers to offer extensions and additions which could build on already known mask aligner technology or extend the latter. The advantage of mask aligners consists primarily in that in most cases they already provide optical systems, in particular lamp houses, for the in particular full-area illumination of the substrates and thus of the embossed embossing materials.

Apart from modified and extended mask aligners, there are also dedicated imprint systems, which are produced on and for special embodiments. The systems are usually alignment systems which can align a stamp with the substrate with a high degree of precision. Furthermore, these systems also provide the possibility of generating a vacuum, special dispensing systems and further modules. Such imprint systems are rarely capable of embossing an embossing material on a substrate of more than 300 mm.

Imprint systems exist which are capable of producing structures for display devices, i.e. displays, in particular curved or flat picture screens.

There are five known techniques in imprint lithography:
micro- and nano-contact printing (μ/nCP)
replica casting (REM)
micro-transfer moulding (μTM) or nanoprint lithography (NIL)
micro-forming in capillaries (MIMIC)
solution-supported micro-moulding (SAMIM)

It is known that imprint stamps can be divided in particular into two large families: use can be made of hard stamps (made of metal, ceramic materials or voluminous glass or plastic) or so-called soft stamps (made of polymers, silicones etc.).

All imprint stamps have a structured stamp surface, which is usually the negative of the structuring to be produced and is impressed in the embossing material.

Soft stamps are produced as the negative of a master stamp. Master stamps are stamps which are used for the primary formation of the soft stamp. In other words, master stamps are templates for the replication. A master stamp is either a hard stamp made of metal, glass, in particular quartz glass, plastic or ceramic, which is produced once by correspondingly expensive processing, or a soft stamp to be impressed, in particular a soft stamp with an elastic, stiffened carrier.

As many soft stamps as desired can be produced from the master stamp. As is known, the soft stamps enable a conformal, uniform contact over large surfaces.

Both the master stamp can be separated from the soft stamp and also the soft stamp from the embossed surface of the substrate free from damage. A fault-free separation of the soft stamp from the master stamp is essential for the production of functioning products. The separability can be the result of a small surface energy of a soft stamp, which is achieved by means of functionalisation, in particular coating. It is for this reason that soft stamps are coated with an anti-adhesion layer (so-called anti-sticking layer, non-sticking layer, ASL layer) after the embossing with the master stamp and curing of the soft stamp embossing compound.

Soft stamps can more easily be separated from the substrate than hard stamps. For the automated implementation of soft-lithographic processes, it is preferable to support the soft stamp by means of a carrier. Glass carrier substrates with varying thicknesses currently find widespread use. By using thick glass substrates, however, the soft stamp loses, at least partially, its flexibility.

Glass carriers are thus sufficiently thin carriers made of glass, which provide the necessary stability for the soft stamp, but are sufficiently flexible to achieve the necessary flexibility. It is also possible to use as a carrier a polymer film and/or a deformable thin glass plate as well as a composite material, in order to enable and facilitate the handling of the stamp. A soft stamp reinforced with a carrier has an increased strength adjustable by design and rigidity as well as an increased dimensional stability compared to soft stamps which are not reinforced.

Other embodiments of soft stamps are produced as layer systems of elastomer or of polymer. The mechanical properties such as stability, elasticity, flatness, roughness, can also be decisively determined by the carrier. The structures of the soft stamp are produced from the soft stamp material, in particular by means of impression by the master stamp.

A master stamp or a hard stamp can be produced in particular in a step-and-repeat process (S&R process). It is chiefly advantageous when very large master stamps have to be produced. The master stamp is produced by a further master-master stamp. In the specialist language, however, the master stamp, by means of which the soft stamps are impressed, is mainly called a sub-master stamp and the master stamp for the production of the sub-master stamp is called a master stamp. The definitions can thus vary. It is disclosed that an, in particular, large-area master stamp (for example a sub-master stamp), which is used for the impression of soft stamps, can be produced by a repeated embossing process (step-and-repeat process), which is distinguished by the fact that embossing is carried out at a first point, then the master stamp-master stamp (or master stamp) is moved and then embossing is carried out at least once more.

For the precise impression of a master stamp, it is necessary that the soft stamp material has an adhesion to the master stamp that is as strong as possible, in order to obtain a fault-free nestling of the embossing material with the master stamp and thus a precise impression of the master stamp. At the same time, it is necessary that the soft stamp material has a low degree of adhesion to the master stamp, in order that the separability of the master stamp from the primary-formed soft stamp can take place. These considerations apply both to master stamps impressed once, master stamp-master stamp, and to step-and-repeat master stamps or the stamp itself. Furthermore, it is conceivable for a master stamp to be used in a step-and-repeat process, in order to emboss the soft stamp directly. This is chiefly advantageous when the soft stamp is very large. The master stamp is moved into a first position, embosses the soft stamp there, then moves to a second position, different from the first position, and embosses again. This process can be continued until such time as a soft stamp of any size has been produced. In particular, the individual points of the embossed soft stamp are impressed in a seamless manner.

A further problem consists in the release of the soft stamp from the surfaces. The soft stamp release must take place in a precisely controlled manner, so that the impressed soft stamp structure and the soft stamp do not suffer any damage during the demoulding of the master stamp.

During the impressing of a soft stamp, deformations due to the material stress can distort the true dimensions of the embossed soft stamp structures, so that the dimensional stability and the separability of the embossed soft stamp structures are a core problem of the embossing process. In particular, a change in the length of the soft stamp without additional compensation changes the material stress, which also means a change in the dimensional stability of the stamp.

The prior art for micro- and/or nano-structuring of surfaces largely comprises photolithography and different embossing techniques. The embossing techniques work either with hard or soft stamps. Above all, embossing lithography techniques are recently gaining acceptance and are ousting classic photolithography techniques. Among embossing lithography techniques, the use of so-called soft stamps are chiefly becoming popular.

The reason lies in the easy production of the stamps, efficient embossing processes, very good surface properties of the respective stamp materials, the low costs, the reproducibility of the embossed product and above all in the possibility of elastic deformation of the stamp during the embossing and the demoulding. A stamp made of an elastomer with a micro- or nano-structured surface is used in soft lithography to produce structures in the range from less than 10 nm to greater than 1000 μm relative to the structure heights. It is possible to produce structure widths of a few centimetres, in particular for Fresnel lenses.

An important feature for the characterisation of the finished soft stamp is the roughness, which can reach values (Ra or Rz values) of less than 10 nm, preferably less than 5 nm. Irrespective of this, the structure sizes can preferably be produced from 10 nm.

Apart from the advantages of imprint lithography with a soft stamp, there is the drawback with the same technology which results from the elasticity of the stamp, so that the dimensional stability of the stamp is not always guaranteed. This leads to inaccuracies and distortions of the formed, embossed structures compared to the embossing structures of the stamp.

It is object of the invention, therefore, to specify an improved method for the production, in particular the embossing, of a soft stamp, which at least partially eliminates, in particular completely eliminates the drawbacks mentioned in the prior art.

Furthermore, it is an object of the present invention to specify a method, which permits an efficient and rapid production of suitable soft stamps. In addition, it is an object of the present invention to specify a device for performing the method for embossing, as well as a soft stamp which can easily be separated from a substrate with the subsequent use of the embossed soft stamp.

The present problems are solved with the features of the coordinated claims. Advantageous embodiments of the invention are given in the sub-claims. All combinations of at least two features stated in the description, in the claims and/or the drawings fall within the scope of the invention. In the case of stated value ranges, values lying within the stated limits should also be deemed to be disclosed as limiting values and can be claimed in any combination.

Accordingly, the invention relates to a method for the production, in particular the embossing, of a soft stamp with the following steps: i) provision of a hard stamp with a first layer, ii) application of a second layer directly on the first layer, iii) embossing of the soft stamp using the hard stamp, wherein the second layer is fixed on the soft stamp, iv) separation of the soft stamp from the hard stamp, so that the second layer is transferred onto the soft stamp.

In other words, during the embossing, i.e. the impressing, of the structures of the master stamp or the hard stamp on the soft stamp, a further layer, in particular a functional layer, preferably an ASL layer, is provided on the first layer. In this connection, the soft stamp to be embossed can also only be formed from a soft stamp embossing compound, which is preferably directly transferred onto the second layer.

Surprisingly, it has been shown that, especially with a corresponding suitable material combination, an anti-adhesion effect can be generated directly on the soft stamp or the surface to be embossed. Advantageously, the functionalisation or adhesion reduction of the surface of the soft stamp can already take place during the embossing. A subsequent and additional coating step can thus be dispensed with, since the soft stamp is already coated with a second layer during the embossing. Furthermore, contamination of the soft stamp can thus be prevented, since the soft stamp can be used directly after the embossing and is directly functionalised or surface-treated by the additional layer.

The steps are preferably carried out in the aforementioned sequence. In the embossing, the structures of the hard stamp are transferred onto the soft stamp or are impressed on the latter. Furthermore, the application of the second layer can also already have taken place, so that a hard stamp with the two layers arranged one above the other is directly provided. The soft stamp makes contact with the second layer during the embossing. The structures of the hard stamp are impressed onto the soft stamp through the layers, since they are very thin layers. The first layer covers the surface of the structures of the hard stamp preferably completely or over the whole area. In the embossing, the second layer adheres to the now structured surface of the soft stamp. In other words, the second layer is fixed on the soft stamp. The materials are preferably selected such that the adhesive strengths between the two layers are at least less than the adhesive strength between the two layers and the soft stamp. In this way, the second layer can advantageously be transferred onto the soft stamp in the course of moving apart or separating the hard stamp and the soft stamp.

In a preferred embodiment of the embossing process, provision is made such that a soft stamp embossing compound of the soft stamp is deposited directly on the second layer in step iii) during the embossing. In other words, the soft stamp embossing compound is directly deposited on the second layer for the embossing, in particular before the transfer of the structures due to the embossing forces starting to take effect. The soft stamp embossing compound is provided directly on the second layer preferably before the embossing step when the soft stamp makes contact with the hard stamp. In this way, it is ensured that the second layer can advantageously be provided directly and without contamination on the embossed and thus functionalised soft stamp.

In a preferred embodiment of the embossing process, provision is made such that the embossing further comprises in step iii) curing of the soft stamp. The soft stamp can be held for example by a carrier transmissive for specific wavelengths, a frame or film, and can be cured through the latter by means of radiation. The curing can also take place by other known measures. During the curing, the adhesive strengths between the soft stamp and the two layers is particularly advantageously increased, so that a strong bond is produced. In this way, a separation can be carried out particularly fault-free and easily. In this embodiment, it is preferable that the material of the second layer and the material of the soft stamp are compatible during the curing, so that a further fixing of the second layer on the soft stamp takes place.

In a preferred embodiment of the embossing process, provision is made such that the first layer is completely wetted by the second layer during the application in step ii). In this way, the entire soft stamp surface to be structured can be functionalised or coated during the embossing.

In a preferred embodiment of the embossing process, provision is made such that the first layer and the second layer are anti-adhesion layers in order to reduce the adhesive forces between the interfaces. The two layers are thus known anti-adhesion layers, which functionalise the adhesive properties of the soft stamp in such a way that, in the subsequent transfer of the structures of the soft stamp onto a product or substrate, said soft stamp can be separated or removed from the latter easily and efficiently. An anti-adhesion coating can thus advantageously take place directly during the embossing of the soft stamp. The interfaces between the two layers and respectively between the layers and the hard stamp or the soft stamp can thus advantageously be adjusted in terms of their adhesive properties. The adhesion between the layers is preferably small, in order that the separation of the second layer from the first layer, which preferably remains on the hard stamp after the separation, and the separation of the stamp can easily be carried out.

In an alternative preferred embodiment of the method for the production of a soft stamp, in particular for the embossing of soft stamps, provision is made such that i) the first layer is deposited on the hard stamp, and ii) the second layer is deposited on the hard stamp and iii) the soft stamp embossing compound is deposited on a carrier, so that for the production of a soft stamp iv) the soft stamp embossing compound is contacted in particular over the whole area with the second layer and v) the soft stamp is then cured. After curing of the soft stamp, vi) the separation of the soft stamp from the hard stamp takes place, wherein the separation takes place between the first layer and the second layer.

In a preferred embodiment of the embossing process, provision is made such that the anti-adhesion layers comprise at least partially tridecafluoro-1,1,2,2-tetrahydrooctyltrichlorosilane [CF3-(CF2)5-(CH2)2-SiC13], and/or 1,1,2,2-perflorodecyltrichlorosilane [CF3-(CF2) 7-(CH2)2-SiC13], and/or 1H,1H,2H,2H-perfluorooctyltrimethoxysilane [CF3-(CF2) 5-(CH2)2-SiO(CH3)3, F13-TMS], and/or perfluoropolyether molecules. The layers can also consist of these materials. These materials have proved to be particularly suitable for use as anti-adhesion layers for soft stamp functionalisation or soft stamp embossing.

In a preferred embodiment of the embossing process, provision is made such that the respective materials of the first layer and the second layer are different. It has also proved to be advantageous that the materials are at least not identical. In this way, the adhesive properties required for the transfer or suitable adhesive forces are provided at the corresponding interfaces. The additional second layer to be transferred, preferably the ASL layer, can advantageously be deposited on the first layer and fixed during the embossing directly on the soft stamp. The soft stamp is thus coated simultaneously during the embossing.

Surprisingly, it has been shown that the properties of the soft stamp embossing material can be optimised by means of the first layer and the second layer. In particular, the filling behaviour of the soft stamp embossing compound can be advantageously influenced by adapting the hydrophilic and/or hydrophobic properties. Furthermore, the electrostatic behaviour of the ready-cured soft stamp can be influenced by the selection in particular of the second layer. The conductivity of the soft stamp can thus be influenced and adjusted via the electrical conductivities of the first layer and the second layer.

In further, less preferred embodiments of the method for the production of soft stamps and for the embossing, provision is made such that at least one further layer, in addition to the first layer and to the second layer, can be used in particular for the adjustment of the surface properties of the hard stamp and the soft stamp. The surface properties can in some cases be adjusted more easily with a plurality of thin layers than with two layers. It is disadvantageous for the method, however, for the layer sequences to have to be built up with more than two layers. The production costs are thus increased and the susceptibility of the method to errors is raised.

In a preferred embodiment of the embossing process, provision is made such that the first layer and the second layer each have, in particular along a structured surface of the hard stamp, a uniform thickness of less than 5 nm, preferably less than 3 nm, particularly preferably less than 1 nm, most preferably 0.3 nm. In other words, the height of the layer along the stamp surface or structured surface is constant. In this way, the embossing structure to be transferred can advantageously be impressed. Due to the small thickness or height, it is also ensured that the fine structures can also be imaged on the soft stamp. In addition, a particularly thin layer is surprisingly sufficient for the functionalisation of the soft stamp with regard to the adhesion properties if a second anti-adhesion layer is provided on the first.

In a further embodiment of the embossing process, provision is made such that the first layer and the second layer each have, in particular along a structured surface of the hard stamp, a uniform thickness less than 30 μm, particularly preferably less than 15 μm, very particularly preferably less than 10 μm.

These layer thicknesses are necessary in particular with large structures, when the structure size in a z-direction to the layer thickness can be up to 1000:5 (both values preferably in nm).

In a preferred embodiment of the embossing process, provision is made such that the first layer and/or the second layer are applied with spin coating, spray coating, chemical phase deposition (CVD), plasma-assisted chemical gas phase deposition (PECVD), physical gas phase deposition (PVD), dip coating, by squeegee or by molecular beam epitaxy (MBE). The application of the second layer can thus take place with the aforementioned methods. These methods are particularly suitable for depositing corresponding thin functional layers uniformly, wherein the embossing structure can at the same time be precisely impressed.

In a further embodiment of the embossing process, provision is made such that the soft stamp at least partially comprises polydimethylsiloxane (PDMS), and/or perfluoropolyether (PFPE), polyhedral oligomeric silsesquioxane (POSS) and/or polydimethylsiloxane (PDMS) and/or tetraethyl orthosilicate (TEOS) and/or poly(organo)siloxane (silicone) and/or thermoplastics and/or thermosetting plastics. The entire soft stamp or the soft stamp embossing compound to be embossed can consist of the aforementioned materials.

In a preferred embodiment of the embossing process, provision is made such that, during the separation, a first adhesive force between the second layer and the first layer is less than a second adhesive force between the second layer and the soft stamp. The materials are selected accordingly.

In addition, the force required for the separation can advantageously be adjusted. For example, the adhesion of the hard stamp and the first layer can in addition be selected such that the latter remains on the hard stamp during the separation. In other words, it is advantageous that only the second layer can be transferred onto the soft stamp.

In a preferred embodiment of the embossing process, provision is made such that the hard stamp is constituted by at least one of the following materials: glass, metal, metal alloy, ceramic or semiconductor material, preferably silicone, cured polymer. These materials are predestined for use in the advantageous embossing process as a hard stamp or master stamp.

In a further preferred embodiment of the method for embossing, provision is made such that the hard stamp comprises cured polymer as the stamp surface. The hard stamp is preferably reinforced with a rigid carrier. The composed hard stamp thus consists of a rigid carrier and of the cured impressed surface of polymer. It has been shown that this embodiment is particularly advantageous for the embossing quality.

Furthermore, the invention relates to a device for the embossing of a soft stamp with a hard stamp according to the method according to at least one of the preceding claims, at least comprising a hard stamp with a first layer, coating means for the application of the second layer on the first layer, embossing means for the embossing of the soft stamp with the hard stamp, wherein the second layer can be fixed on the soft stamp, separation means for separating the soft stamp from the hard stamp, wherein the second layer can be transferred onto the soft stamp.

In other words, a layer, preferably an anti-adhesion layer, can be directly transferred onto the soft stamp during the embossing with the device, since two layers arranged directly one above the other are provided on the master stamp or a hard stamp. The device is designed precisely to enable the embossing of the soft stamp and precisely to perform a functionalisation with regard to the adhesion properties of the structured soft stamp. The device preferably comprises means for depositing a soft stamp embossing compound directly onto the second layer, in particular before the embossing means starts to act. The means are in particular designed to provide the soft stamp embossing compound on the second layer before the embossing. Embossing can thus advantageously be carried out precisely. In addition, impurities between the second layer and the soft stamp moulding compound and thus between the embossed soft stamp and the second layer fixed thereon after the embossing are prevented.

In a preferred embodiment of the device, provision is made such that the device also comprises curing means for hardening the soft stamp, wherein the curing means are designed to cure the soft stamp during embossing before the separation means acts. The curing means can for example be heat, electromagnetic radiation, in particular UV radiation etc. The use of radiation, in particular through a carrier/frame of the soft stamp, is preferable for the curing. Advantageously, the second layer can thus be cured and fixed on the soft stamp at the same time. In this way, a straightforward and fault-free separation along the interface can be carried out more easily.

The surprising knowledge underlies the invention that a master stamp can be coated with a layer for the functionalisation, in particular with low adhesion (so-called anti-sticking layer, non-adhesive layer, ASL layer, anti-adhesion layer) and a second functional layer different from the first layer, in particular with an ASL layer, which is deposited on the first layer in order then to impress a soft stamp by the master stamp. During the separation of the soft stamp from the master stamp, the interface between the first ASL layer and the second ASL layer serves as a parting surface. When the soft stamp is impressed, the first ASL layer remains on the master stamp. During the curing of the soft stamp embossing compound, the second ASL layer becomes part of the impressed soft stamp, which as the ASL layer is used for the surface functionalisation.

It is an aspect of the invention to specify a method, with the aid of which an anti-adhesion layer can be transferred during the impressing of a soft stamp directly from the master stamp onto the soft stamp.

ASL layers are provided as molecular layers with at least one molecule layer, preferably a molecular layer with an in particular cohesive molecule layer, which functionalises the soft stamp and/or the master stamp.

The soft stamp adheres to the master stamp as a result of the combination of mechanical and/or physical and/or chemical reasons: mechanical reasons are the surface enlargement of the soft stamp due to the structuring, the friction between the master stamp and soft stamp and a form-fit of the soft stamp embossing compound with the master stamp.

The physical basis of the adhesion property results primarily from the van-der-Waals forces and/or the hydrogen bridge bonds.

The chemical basis of the adhesion property results from the chemical bonds: ionic and/or covalent, atomic and/or metallic bonding.

The actual adhesive property between the master stamp and the soft stamp is a resultant effect arising from a combination of the three stated bases. If the resultant adhesion property is great, there is the risk of an imprecise impression and/or tearing-off of the soft stamp.

It is known to the person skilled in the art to use functional layers, in particular those for the reduction of the adhesion properties, so as to be able to impress the soft stamp in the optimum manner by the hard stamp. These anti-adhesion layers are important for the further use of the structured or embossed soft stamp, since the soft stamps can otherwise be impressed on a substrate after the generation of the structure and can only be separated from the latter with difficulty.

Contrary to the current teaching, at least one further functional layer, in particular a further ASL layer, is deposited. This further functional layer remains in particular directly on the impressed soft stamp and does not have to be deposited in yet another process step.

The aim is to apply a functional layer on the soft stamp during the production of the soft stamp, so that a functional layer also remains on the soft stamp during the demoulding of the soft stamp from the master stamp. From the structural standpoint, it is advantageous in general to avoid undercuts in the structure.

The adhesion properties of the individual soft stamp materials can thus be adapted to one another in such a way that the dimensional stability and embossing accuracy is increased and at the same time the required separating force of the soft stamp from the master stamp is reduced. The adhesion properties should in general be reduced for this purpose.

At the same time, the ASL layers cause a reduction in friction due to the chemical and/or physical smoothing of the surfaces, which in effect can be equated with lubrication, even though no conventional wetting lubricants are used.

The conditions for a stamp with dimensional stability comprise the following features and/or properties:

Dimensional stability means that the surface is imaged with the 3D surface profile of the master stamp error-free into the soft stamp and this shape is maintained after the demoulding.

In cross-section, the stamps have the following spatial sequence during embossing in a preferred embodiment:
Master stamp,
first interface: master stamp surface to first ASL surface,
first ASL layer,
second interface; first ASL surface to second ASL surface. When the soft stamp is separated from the master stamp, the embossed soft stamp and its ASL layer are separated from this interface,
second ASL layer,
third interface: second ASL surface to the soft stamp surface,
soft stamp,
fourth interface: soft stamp surface to the carrier,
carrier/frame/film.

The individual elements of the sequence or the stack are described in the following. The master stamp is preferably made of glass, a metal, a metal alloy, a ceramic or a semiconductor material such as silicone.

The following properties are preferred for the master stamp material. High frictional strength, high rigidity, low thermal expansion, high thermal conductivity, low porosity, chemical inertia at the operating temperature, as well as an anisotropy characterise the master stamp bulk material. The bulk material is used far below the strain limit in order to ensure the dimensional stability of the master stamp, so that the elasticity of the master stamp is in particular two orders of magnitude less than the elasticity of the cured embossing compound. The elasticity is characterised by the modulus of elasticity, which for the master stamp can preferably have at least double-digit values in gigapascals. Master stamps can also be cured soft stamps made of polymers and elastomers or silicone. The production of the hard master stamp preferably takes place with electron beam lithography.

The application of the ASL layers takes place with the aid of the known coating methods of thin layer technology, in particular for liquid layers. In general known under the generic term “coating”. Coating includes spin coating, spray coating, chemical vapour deposition (CVD), plasma-assisted chemical gas vapour deposition (PECVD), physical gas phase deposition (PVD), dip coating, by squeegee and molecular beam epitaxy (MBE), with which the material is coated by reaction of volatile initial substances or by condensation from the vapour phase on an already present layer or substrate surface, in particular on the master stamp surface.

First interface: The structured and impressed master stamp surface is coated with a layer for the functionalisation of the master stamp surface, with the first ASL material. The coating material is used preferably to produce an in particular cohesive monoatomic and/or monomolecular layer on the master stamp surface.

The first ASL material should preferably produce a physical and/or chemical bond with the master stamp material. In the first interface, the geometry of the master stamp surface should preferably not be changed due to the monomolecular and/or monoatomic first ASL layer. In alternative embodiments of the embossing process, the layer thickness of the first ASL layer is taken into account in the production of the master stamp structures, so that the correct impression dimensions of the master stamp with the coating of the first ASL layer produce the required structure sizes.

It is possible that, after the coating of the master stamp with the first ASL material, the first interface bonds with the master stamp due to a chemical and/or physical reaction of the first ASL material, but the functionalising surface properties of the first ASL layer are retained.

The purpose of the first ASL layer on the master stamp is to receive the second ASL layer, which remains on the soft stamp during the demoulding of the soft stamp from the master stamp.

The adhesion property of a surface can be expressed by the energy density. The energy density is derived from the force required for the separation of two surfaces. In the knowledge of the size of the separated surface, the person skilled in the art can, at least approximately, estimate the surface energy from the measured force for the separation of a stamp from a master. The energy density can be estimated from the surface energy.

Depending on the given embodiment, the mechanical force can occur as a shearing force or as a normal force. In the case of normal forces, it can be a point force, a linear force or an area force. The energy per unit area is optimally used for the separation of two surfaces, referred to in the subsequent text as energy density that is required for the separation of two bodies.

The energy density between the first layer and the second layer is less than 100 mJ/m2, preferably less than 30 mJ/m2, particularly preferably less than 15 mJ/m2, in the optimum case less than 10 mJ/m2, as measured after the curing at the given temperature (in particular at over 70 °C).

The first ASL layer preferably consists of a single atomic and/or molecular layer, which wets the master stamp surface.

A first ASL material is selected which has a very good adhesion property to the master stamp surface.

The first ASL material has very good abrasion properties, so that a grinding deposition is largely prevented or at least minimised.

For the first ASL material, a solid material with marked polar-anisotropic properties is preferably used for the adjustment of the adhesion properties of the master stamp. A contact angle measurement can be used for the measurement of the adhesion property. The contact angle is a measure for the hydrophobicity or hydrophilicity which is formed between a test liquid droplet and the surface to be measured. Hydrophilic surfaces flatten the liquid droplet, since the adhesive forces between the liquid and the surface dominate over the cohesive forces of the liquid and thus form small contact angles. Hydrophobic surfaces lead to a spherical shape of the liquid droplet, since the cohesive forces of the liquid dominate over the adhesive forces between the liquid and the surface. Hydrophilic surfaces have a higher surface energy than hydrophobic surfaces.

Water can be used as the test liquid for a contact angle measurement of a solid body surface such as the master stamp, the first ASL and the second ASL surfaces and the soft stamp surface.

According to the invention, the separation between the master stamp and the soft stamp takes place along the second interface, which is formed by the first ASL and the second ASL surfaces.

The second interface particularly preferably has the lowest surface energy of all the interfaces in the process for the embossing or the coating of the master stamp and the separation of the soft stamp from the master stamp.

For this purpose, the material pairing of the first ASL and second ASL material is selected such that the two materials have the least affinity to one another. Surprisingly, it has advantageously been shown that, in the layer build-up for the impression of the soft stamp by the master stamp, there should be deposited on the first ASL layer a further second ASL layer different from the latter and then the master stamp should be impressed.

At least the second ASL layer is preferably a monoatomic or monomolecular layer.

The third interface is formed between the second ASL surface and the soft stamp surface. In this interface, a high degree of affinity of the materials to one another is present, so that the second ASL layer remains adhering to the soft stamp during the separation of the master stamp from the soft stamp.

In particularly preferred embodiments, the third interface at least partially disappears, so that the anti-adhesion property of the second ASL material is integrated into the soft stamp. In other words, an at least partial material integration of the second ASL material into the soft stamp material takes place. A material transport from the soft stamp material into the second ASL material or vice versa is sub-optimal. The material pairing is carried out in such a way that diffusion is minimised as far as possible. At least one insoluble bond preferably takes place between the second ASL material and the soft stamp material, in particular during embossing.

The soft stamp material comprises at least the following properties:

the soft stamp material can be applied by a coating process on the second ASL material.

The latter can be coating processes used in semiconductor technology or coating technology, in particular spray coating, spin coating with so-called puddle dispense or after deposition in a pattern, by squeegee, screen-printing, inkjet printing.

The soft stamp material can be transformed in a thermochemical or photochemical reaction from the state as a monomer into a polymer and thus acquire the necessary properties of strength and dimensional stability.

The soft stamp material is dimensionally stable and long-term stable, absorbing in the wavelength range for its own cross-linking radiation, but transparent for the cross-linking radiation of the embossing process with which a product is to be embossed with the soft stamp in subsequent process steps. The soft stamp material and the embossing material can be crosslinked with the same wavelength and/or the same wavelength range in the case of preferred soft stamp materials. The transparency, measured as transmittance, can lie over 70%, preferably over 80%, particularly preferably over 90%, in the optimum case over 95%, so that a high proportion of the cross-linking radiation penetrates and reacts in the embossing material.

In order to obtain the dimensional stability of the soft stamp material, the soft stamp material must be sufficiently rigid. At the same time, the soft stamp material is elastic, in order to return into the shape obtained in the original moulding after the demoulding from the master stamp and/or a component subsequently to be embossed. Furthermore, the soft stamp material requires elasticity in order to withstand the forces of the demoulding and not to tear. In particular, soft stamp materials are used, the elasticity of which, in particular the non-linear elastic material behaviour of which and the rigidity of which leads to the optimum demoulding behaviour.

The fourth interface is constituted between the soft stamp material and the carrier. A high, in particular extremely high affinity of the soft stamp material to the carrier material is present in this interface, so that the carrier adheres firmly to the soft stamp.

An increased degree of adhesion is preferably present between the carrier and the soft stamp after a plasma activation at least of the carrier surface compared to a bond that is not surface-activated.

The carrier material preferably comprises at least one material of the following materials classes:
metallic glasses
non-metallic glasses, in particular
   organic non-metallic glasses
   inorganic non-metallic glasses, in particular
      non-oxidic glasses, in particular
         halogenide glasses
         chalcogenide glasses
      oxidic glasses, in particular
         phosphatic glasses
      silicate glasses, in particular
         aluminosilicate glasses
         lead silicate glasses
         alkali silicate glasses, in particular
         alkali-earth alkali silicate glasses
         borosilicate glasses
         quartz glass
         borate glasses, in particular
         alkali borate glasses
Materials which are denoted as glasses but which are not such, in particular sapphire glass or metal, in particular at least one element from the list Cu, Ag, Au, Al, Fe, Ni, Co, Pt, W, Cr, Pb, Ti, Ta, Zn, containing,
technical ceramics,
carbon (graphite, graphene, DLC)
polymers, in particular
   Polyurethane, Hypalon (material), isoprene rubber (material), nitrile rubber (material), perfloro-rubber (material), polyisobutene (material), thermoplastic elastomers, foams, in particular Arcel (material), Neopor (material), polyisocyanurate, polystyrenes, cellular rubber, acrylester-styrene-acrylonitrile, acrylonitrile/methyl methacrylate, acrylonitrile/butadiene/acrylate, acrylonitrile/chlorinated polyethylene/styrene, acrylonitrile/butadiene/styrene, acryl polymers, alkyd resins, butadiene rubber, butyl rubber, casein plastics, synthetic horn, cellulose acetate, cellulose ether and derivatives, cellulose hydrate, cellulose nitrate, chitin, chitosan, chloroprene rubber, cyclo-olefin-copolymers, uniform polyvinyl chloride, epoxy resin, ethylene-ethyl acrylate copolymer, ethylene-polyvinyl acetate, ethylene-propylene copolymer, ethylene-propylene-diene rubber, ethylene vinyl acetate, expandable polystyrene, fluoro-rubber, urea formaldehyde resin, urea resins, isoprene rubber, lignin, melamine formaldehyde resin, melamine resins, methyl acrylate/butadiene/styrene, natural rubber, perfluoroalkoxyalkane, phenol-formaldehyde resin, polyacetals, polyacrylonitrile, polyamide, polybutylene succinate, polybutylene terephthalate, polycaprolactone, polycarbonate, polycarbonates, polychlorotrifluoroethylene, polyester, polyester amide, polyether alcohols, polyether-block-amide, polyether imide, polyether ketones, polyether sulphone, polyethylene, polyethylene terephthalate, polyhydroxyalkanoates, polyhydroxy butyrate, polyimide, polyisobutylene, polylactide (polylactic acid), polymethacryl methylimide, polymethyl methacrylate, polymethyl pentene, polyoxymethylene or polyacetal, polyphenylene ether, polyphenylene sulphide, polyphthalamide, polypropylene, polypropylene copolymers, polypyrrole, polystyrene, polysulfone, polytetrafluoroethylene, polytrimethylene terephthalate, polyurethane, polyvinyl acetate, polyvinyl butyral, polyvinyl chloride (hard PVC), polyvinyl chloride (soft PVC), polyvinylidene fluoride, polyvinyl pyrrolidone, styrene-acrylonitrile copolymerisate, styrene-butadiene-rubber, styrene-butadiene-styrene, synthetic rubber, thermoplastic polyurethane, unsaturated polyester, vinyl acetate copolymers, vinyl chloride/ethylene/methacrylate, vinyl chloride/ethylene, vinyl chloride-vinyl acetate copolymers, plasticised polyvinyl chloride.

The carrier can consist of a plurality of layers in a further embodiment. The carrier serves as a mechanical stabiliser for the soft stamp. The carrier material is transparent for cross-linking radiation of the soft stamp. In other words, the transmittance preferably amounts to greater than 80%, particularly preferably greater than 90%, very particularly preferably greater than 95%, in the optimum case greater than 98% with the given thickness of the carrier material.

ASL materials can in particular contain at least in part tridecafluoro-1,1,2,2-tetrahydrooctyltrichlorosilane [CF3-(CF2) 5-(CH2)2-SiC13], and/or 1,1,2,2-perflorodecyltrichlorosilane [CF3-(CF2) 7-(CH2)2-SiC13], and/or 1H,1H,2H,2H-perfluorooctyltrimethoxysilane [CF3-(CF2) 5-(CH2)2-SiO(CH3)3, F13-TMS], and/or perfluoropolyether molecules.

Soft stamp materials can in particular contain at least in part polydimethyl siloxane (PDMS), and/or perfluoropolyether (PFPE), polyhedral oligomeric silsesquioxane (POSS) and/or polydimethyl siloxane (PDMS) and/or tetraethyl orthosilicate (TEOS) and/or poly(organo)siloxane (silicone) and/or thermoplastics and/or thermosetting plastics.

### Method

A direction is not indicated by any of the pronouns such as above or below, but only a relationship. Thus, the coating of the master stamp and the primary forming of the soft stamp embossing compound are possible against the direction of gravitation. The following text describes the method in such a way that the master stamp or hard stamp is located at the underside and the soft stamp at the upper side.

A first embodiment of an exemplary process for the embossing consists in the following steps, in particular carried out at least after one another and/or simultaneously, in particular with the following sequence:

The master stamp is coated with a first ASL layer in a first process step.

Furthermore, it is possible that at least the first ASL layer has a self-assembly property.

Furthermore, it is possible that at least the first ASL layer is deposited on the master stamp in a plasma deposition process.

The first ASL material is applied on the master stamp in such a way that the highly adhesive side of the first ASL layer adheres to the master stamp. The low-adhesive side of the first ASL layer points away from the master stamp. The first ASL layer wets the master stamp structures in the best possible manner.

After the coating with a first ASL layer, the master stamp can undergo an optional intermediate step for the modification and/or curing and/or cross-linking of the first ASL layer. The first ASL layer can preferably form a chemical bond with the master stamp surface, so that, from the macroscopic standpoint, the adhesion of the first ASL layer is greater than the adhesion of a Langmuir-Blodgett film. An adaptation of a surface can be understood as the production of a first layer. Accordingly, in particular nitridation, oxidation, coatings such as metallisation (nickel-plating, chrome-plating), hardening of the surface or carbon enrichment in the broadest sense can be understood as the production of a first layer.

The surface thus arising is the true impression surface of the master stamp.

In a second process step, the second ASL layer is applied on the first ASL layer. It is important that the first ASL layer has a low affinity to the second ASL layer, so that an easy and as far as possible residue-free separation of the impressed soft stamp from the master stamp is enabled in a further process step.

The second ASL layer differs at least in part from the first ASL layer.

The thickness differences of the first ASL layer and/or the second ASL layer lie in each case less than 5 nm, preferably less than 3 nm, particularly preferably less than 1 nm, in the ideal case less than 0.3 nm.

In a third process step, the soft stamp is impressed on the master stamp. The second ASL layer remains on the soft stamp.

In a fourth, optional process step, the carrier is placed on the rear side of the soft stamp. The soft stamp and the carrier are referred to just as a soft stamp for the sake of simplicity.

The affinity of the second ASL material to the material of the soft stamp is greater than to the first ASL material, in order that an easy separation of the ready-processed soft stamp coated with a second ASL layer from the master stamp with the first ASL layer is enabled.

In a fifth process step, the soft stamp is preferably crosslinked through the carrier. In this process step, the soft stamp acquires the necessary dimensional stability and strength. The cross-linking reaction takes place as a photochemical and/or photo-thermo-chemical or a thermochemical or a delayed chemical reaction.

In this process step, the second ASL layer is joined with the material of the soft stamp preferably in a non-separable, in particular covalent bond. This leads to the actual formation of the parting point between the first ASL layer, which in particular forms a non-separable bond with the master stamp, and the second ASL layer as a component of the soft stamp surface. At the same time, the cross-linking reaction forms a bond of high affinity of the soft stamp material with the carrier.

In a sixth process step, the cured soft stamp is separated from the master stamp.

The soft stamp provided with a second ASL layer can thus be used for the embossing of structures. The aforementioned steps are part of the embossing process.

All the technical terms are used in this disclosure as terms for magnitudes subject to tolerances, even though the tolerances are not explicitly stated. The production and/or measurement tolerances of the data commonly used by engineers apply. The magnitudes without tolerance ranges are stated to make the understanding easier.

Further advantages, features and details of the invention emerge from the following description of preferred examples of embodiment and with the aid of the figures. The same components or components with the same function are denoted by the same reference numbers in the figures. The figures show diagrammatically:

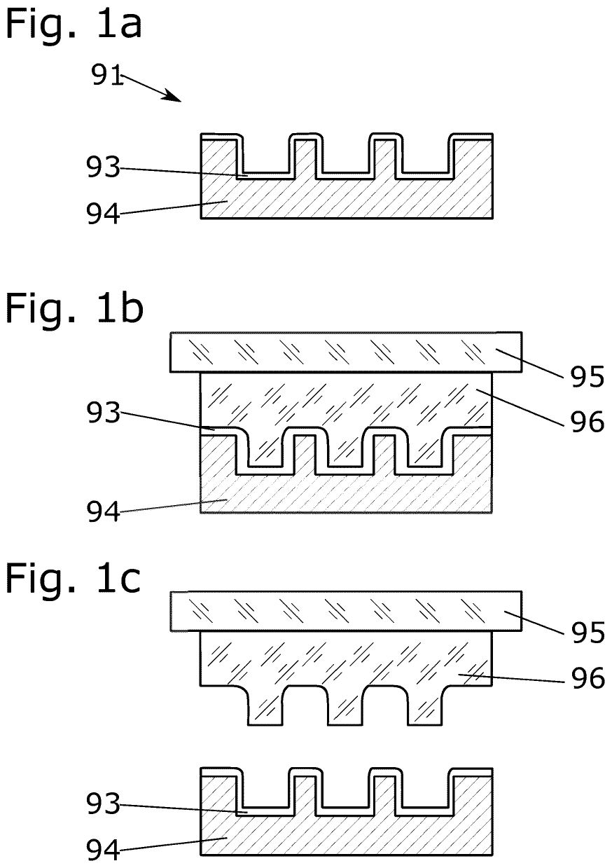

FIG. 1a a diagrammatic representation of a first process step of a method for the embossing of a stamp according to the prior art,

FIG. 1b a diagrammatic representation of a second process step,

FIG. 1c a diagrammatic representation of third process step,

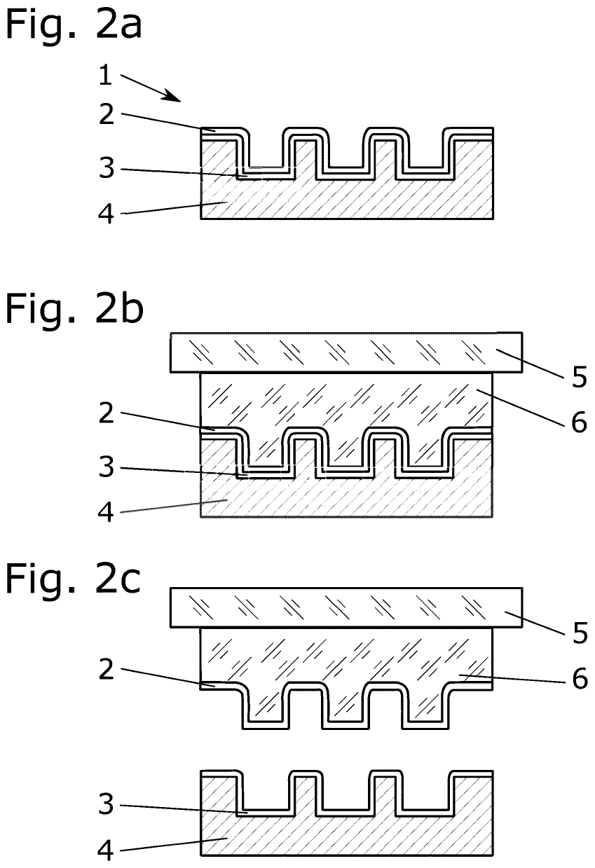

FIG. 2a a diagrammatic representation of a first process step of the method for embossing according to the invention,

FIG. 2b shows a diagrammatic representation of a further process step of the method for embossing according to the invention,

FIG. 2c shows a diagrammatic representation of the stamp after the separation.

The diagrammatic figures serve to illustrate the method.

FIG. 1a shows a coated master stamp 91. Coated master stamp 91 consists of a master stamp 94 and an ASL layer 93. ASL layer 93 is applied on the master stamp surface.

FIG. 1b shows a master stamp 94 with an ASL layer 93 with an already cured soft stamp 96, which is materially connected to a carrier 95. According to this represented process step, the separation of soft stamp 96 takes place together with carrier 95 from master stamp 91. ASL layer 93 remains on master stamp 94. The separation takes place between soft stamp 96 and ASL layer 93.

In other words, soft stamp 96 is separated from coated master stamp 91. The separation itself is not represented.

FIG. 1c represents the state of the process after the separation of soft stamp 96 with carrier 95 from coated master stamp 91. In the prior art, soft stamp 96 is coated separately in a further process and can be used for the embossing of structures on a substrate not represented.

FIG. 2a shows a master stamp 4, which has been coated with a first ASL layer 3 and a second ASL layer 2. Master stamp 4 with both coatings of a first ASL layer 3 and a second ASL layer 2 is characterised as a master stamp 1 coated a number of times.

First ASL layer 3 has a high adhesive strength to master stamp 4 and a low adhesive surface to a second ASL layer 2.

It is advantageous if the coating of first ASL layer 3, which is located on master stamp 4, takes place time-staggered with the second ASL layer, so that mixing the first ASL layer 3 and second ASL layer 2 is prevented.

It is important that second ASL layer 2 completely wets first ASL layer 3 in the processing, but which enables a controlled and energy-stable and dimensionally stable separation, i.e. a very low affinity between first ASL layer 3 and second ASL layer 2 is adjusted as a material pairing.

FIG. 2b shows the result of a further process step for the replication and coating of soft stamps.

Carrier 5 and soft stamp 6 are joined with one another by a high affinity. Soft stamp 6 in particular also has a high affinity to second ASL layer 2. For the primary forming of soft stamp 6, master stamp 1 coated a number of times was thus used: The layer sequence of first ASL layer 3, second ASL layer 2 and soft stamp 6 first was applied on master stamp 4 in the primary forming.

First ASL layer 3 has a high affinity to master stamp 4, but a low affinity to second ASL layer 2.

Second ASL layer 2 has a high affinity to the material of soft stamp 6. Soft stamp 6 also has a high affinity to carrier 5. Soft stamp 6 is stiffened with carrier 5.

It is advantageous to functionalise a soft stamp 6 during the primary forming with an ASL layer, in particular with second ASL layer 2.

FIG. 2c represents the result of the process step for the separation of soft stamp 6 from master stamp 4. Soft stamp 6 has been raised with carrier 5 from master stamp 4. Second ASL layer 2 remains joined to soft stamp 6. Second ASL layer 2 has been separated residue-free from first ASL layer 3 of master stamp 4.

List of reference numbers

| | |
|---|---|
| 1 | master stamp coated a number of times |
| 2 | second layer, ASL layer |
| 3 | first layer, ASL layer |
| 4 | master stamp, hard stamp |
| 5 | carrier, film, frame |
| 6 | soft stamp, soft stamp embossing compound, embossing |
| | compound |
| 91 | master stamp coated once |
| 93 | ASL layer |
| 94 | master stamp, hard stamp |
| 95 | carrier |
| 96 | soft stamp, soft stamp embossing compound |

1. A method for the embossing of a soft stamp, the method comprising:
i) providing a hard stamp with a first layer,
ii) applying a second layer directly on the first layer,
iii) embossing the soft stamp using the hard stamp, the second layer being fixed on the soft stamp, and
iv) separating the embossed soft stamp from the hard stamp to transfer the second layer onto the soft stamp.

2. The method according to claim 1, wherein a soft stamp embossing compound of the soft stamp is deposited directly on the second laver during the embossing.

3. The method according to claim 1, wherein the embossing further comprises curing the soft stamp.

4. The method according to claim 1, wherein the first layer is completely wetted by the second layer during the applying of the second layer.

5. The method according to claim 1, wherein the first layer and the second layer are anti-adhesion layers for reduction of adhesive forces between interfaces.

6. The method according to claim 5, wherein the anti-adhesion layers comprise at least partially tridecafluoro-1,1,2,2-tetrahydrooctyltrichlorosilane [CF3-(CF2) 5-(CH2)2-SiC13], and/or 1,1,2,2-perflorodecyltrichlorosilane [CF3-(CF2) 7-(CH2)2-SiC13], and/or 1H,1H,2H,2H-perfluorooctyltrimethoxysilane [CF3-(CF2) 5-(CH2)2-SiO(CH3)3, F13-TMS], and/or perfluoropolyether molecules.

7. The method according claim 1, wherein materials of the first layer are different from materials of the second layer.

8. The method according to claim 1, wherein the first layer and the second layer each have along a structured surface of the hard stamp, a uniform thickness less than 5 nm.

9. The method according to claim 1, wherein the first layer and/or the second layer are applied with spin coating, spray coating, chemical phase deposition (CVD), plasma-assisted chemical gas phase deposition (PECVD), physical gas phase deposition (PVD), dip coating, by squeegee or by molecular beam epitaxy (MBE).

10. The method according to claim 1, wherein the soft stamp at least partially comprises polydimethylsiloxane (PDMS), and/or perfluoropolyether (PFPE), polyhedral oligomeric silsesquioxane (POSS) and/or polydimethylsiloxane (PDMS) and/or tetraethyl orthosilicate (TEOS) and/or poly(organo)siloxane (silicone) and/or thermoplastics and/or thermosetting plastics.

11. The method according to claim 1, wherein a first adhesive force between the second layer and the first layer is less than a second adhesive force between the second layer layer and the soft stamp.

12. The method according to claim 1, wherein the hard stamp is constituted by one or more materials from the group consisting of glass, metal, metal alloy, ceramic and semiconductor material.

13. A device for the embossing of a soft stamp, the device comprising:
a hard stamp with a first layer,
coating means or applying a second layer on the first layer, and
embossing means or embossing the soft stamp using the hard stamp, the second layer being fixed on the soft stamp,
separation means for separating the embossed soft stamp from the hard stamp to transfer the second layer onto the soft stamp.

14. The device according to claim 13, further comprising:
curing means for hardening the soft stamp during the embossing and before the separating.

15. (canceled)
